(19) United States
(12) Patent Application Publication
(10) Pub. No.: US 2025/0160092 A1
(43) Pub. Date: May 15, 2025

(54) ELECTRONIC DEVICE AND MANUFACTURING METHOD THEREOF

(71) Applicant: Innolux Corporation, Miaoli County (TW)

(72) Inventors: Jui-Jen Yueh, Miaoli County (TW); Kuan-Feng Lee, Miaoli County (TW)

(73) Assignee: Innolux Corporation, Miaoli County (TW)

(21) Appl. No.: 18/912,524

(22) Filed: Oct. 10, 2024

Related U.S. Application Data
(60) Provisional application No. 63/597,696, filed on Nov. 10, 2023.

(30) Foreign Application Priority Data
Aug. 5, 2024 (CN) 202411065634.5

(51) Int. Cl. H01L 27/15; H01L 25/065

(52) U.S. Cl. CPC H10H 29/142; H01L 25/0657; H01L 2225/06548

(57) ABSTRACT

An electronic device and a manufacturing method thereof are provided. The electronic device includes a driving substrate, a connection layer, a plurality of light-emitting elements, and a buffer structure. The connection layer is disposed on the driving substrate. The light-emitting elements are electrically connected to the driving substrate via the connection layer. The buffer structure is disposed on the light-emitting elements and includes a plurality of openings. The openings are overlapped with the light-emitting elements. The buffer structure has a first surface adjacent to the light-emitting elements and a second surface away from the light-emitting elements, and a roughness of the second surface is greater than a roughness of the first surface. The electronic device and the manufacturing method thereof of the disclosure may reduce the probability of light mixing between pixels of different colors or may concentrate light to improve light efficiency.

### CROSS-REFERENCE TO RELATED APPLICATION

This application claims the priority benefit of U.S. provisional application Ser. No. 63/597,696, filed on Nov. 10, 2023 and China application serial no. 202411065634.5, filed on Aug. 5, 2024. The entirety of each of the above-mentioned patent applications is hereby incorporated by reference herein and made a part of this specification.

### BACKGROUND

### Technical Field

The disclosure relates to an electronic device and a manufacturing method thereof, in particular to an electronic device and a manufacturing method thereof that may reduce the probability of light mixing between pixels of different colors or may collect light to improve light efficiency.

### Description of Related Art

Electronic devices or tiled electronic devices have been widely used in different fields such as communication, display, automotive, or aviation. With the rapid development of electronic devices, electronic devices are being developed to be thinner and lighter. Therefore, the requirements for reliability or quality of electronic devices are getting higher.

### SUMMARY

The disclosure provides an electronic device and a manufacturing method thereof that may reduce the probability of light mixing between pixels of different colors or may concentrate light to improve light efficiency.

According to an embodiment of the disclosure, an electronic device includes a driving substrate, a connection layer, a plurality of light-emitting elements, and a buffer structure. The connection layer is disposed on the driving substrate. The plurality of light-emitting elements are electrically connected to the driving substrate via the connection layer. The buffer structure is disposed on the plurality of light-emitting elements and includes a plurality of openings. The plurality of openings are overlapped with the plurality of light-emitting elements. The buffer structure has a first surface adjacent to the plurality of light-emitting elements and a second surface away from the plurality of light-emitting elements, and a roughness of the second surface is greater than a roughness of the first surface.

According to an embodiment of the disclosure, a manufacturing method of an electronic device includes the following steps: providing a base layer; forming a buffer layer on the base layer; forming a light-emitting element layer on the buffer layer; patterning the light-emitting element layer to form a plurality of light-emitting elements; forming a connection layer on the plurality of light-emitting elements; bonding the connection layer onto the driving substrate; applying a laser onto the buffer layer to separate the base layer and the plurality of light-emitting elements from each other; and removing a portion of the buffer layer remaining on the plurality of light-emitting elements to form a buffer structure. In particular, the buffer structure includes a plurality of openings, and the plurality of openings expose the plurality of light-emitting elements.

### BRIEF DESCRIPTION OF THE DRAWINGS

The accompanying drawings are included to further understand the disclosure, and the drawings are incorporated in the specification and constitute a part of the specification. The drawings illustrate embodiments of the disclosure and, together with the description, serve to explain principles of the disclosure.

FIG. 1 to FIG. 6 are schematic cross-sectional views of the manufacturing method of the electronic device of the first embodiment of the disclosure.

FIG. 7 is a schematic cross-sectional view of the electronic device of the second embodiment of the disclosure.

FIG. 8 is a schematic cross-sectional view of the electronic device of the third embodiment of the disclosure.

FIG. 9 is a schematic cross-sectional view of the electronic device of the fourth embodiment of the disclosure.

FIG. 10 is a schematic cross-sectional view of the electronic device of the fifth embodiment of the disclosure.

FIG. 11 is a schematic cross-sectional view of the electronic device of the sixth embodiment of the disclosure.

### DESCRIPTION OF THE EMBODIMENTS

The disclosure may be understood by referring to the following detailed description in conjunction with the accompanying drawings. It should be noted that in order to facilitate understanding to the reader and to simplify the drawings, the multiple drawings in the disclosure depict a part of the electronic device, and certain elements in the drawings are not drawn to actual scale. In addition, the quantity and dimension of each element in the figures are for illustration, and are not intended to limit the scope of the disclosure.

In the following specification and claims, words such as “containing” and “including” are open-ended words, so they should be interpreted as meaning “containing but not limited to . . . ”

It should be understood that, when an element or film is referred to as being “on” or “connected to” another element or film, it may be directly on or directly connected to this other element or layer, or there may be an intervening element or layer in between (indirect case). In contrast, when an element is referred to as being “directly on” or “directly connected to” another element or layer, there are no intervening elements or layers present.

Although the terms “first”, “second”, “third” . . . may be used to describe various constituent elements, the constituent elements are not limited to these terms. These terms are used to distinguish a single constituent element from other constituent elements in the specification. The same terms may be not used in the claims, but are replaced by first, second, third . . . in the order in which elements are declared in the claims. Therefore, in the following specification, a first constituent element may be a second constituent element in the claims.

In this article, the terms “about”, “approximately”, “substantially”, “essentially” usually mean within 10%, or within 5%, or within 3%, or within 2%, or within 1%, or within 0.5% of a given value or range. The quantities given here are approximate quantities, that is, without specific instructions such as “about”, “approximately”, “substantially”, “essentially”, the meanings of “about”, “approximately”, “substantially”, “essentially” may still be implied.

In some embodiments of the disclosure, terms related to joining, connecting, such as “connecting”, “interconnecting”, etc., unless otherwise specified, may mean that two structures are in direct contact, or it may also mean that the two structures are not in direct contact, and there are other structures disposed between the two structures. Moreover, the terms of bonding and connecting may also include the case where both structures are movable or both structures are fixed. In addition, the term “coupling” includes any direct and indirect electrical connection means.

In some embodiments of the disclosure, optical microscopy (OM), scanning electron microscopy (SEM), film thickness profiler (α-step), ellipsometer, or other suitable methods may be used to measure the area, width, thickness, or height of each element, or the distance or spacing between the elements. Specifically, according to some embodiments, a scanning electron microscope may be used to obtain a cross-sectional structure image including the elements to be measured, and measure the area, width, thickness, or height of each element, or the distance or spacing between the elements.

In the disclosure, an electronic device may include a display device, a light-emitting device, a backlight device, a virtual reality device, an augmented reality (AR) device, an antenna device, a sensing device, a tiling device, or any combination thereof, but the disclosure is not limited thereto. The display device may be a non-self-luminous display or a self-luminous display according to requirements, and may be a color display or a monochrome display according to requirements. The antenna device may be a liquid-crystal-type antenna device or a non-liquid-crystal-type antenna device, and the sensing device may be a sensing device that senses capacitance, light, heat energy, or ultrasonic waves, the tiling device may be a display tiling device or an antenna tiling device, but the disclosure is not limited thereto. An electronic element in the electronic device may include a passive element and an active element, such as a capacitor, a resistor, an inductor, a diode, a transistor, etc. The diode may include a light-emitting diode (LED) or a photodiode. The LED may include, for example, an organic light-emitting diode (OLED), a mini LED, a micro LED, or a quantum dot LED (QDLED), but the disclosure is not limited thereto. The transistor may include, for example, a top-gate thin-film transistor, a bottom-gate thin-film transistor, or a dual-gate thin-film transistor, but the disclosure is not limited thereto. The electronic device may also include a fluorescent material, a phosphor material, a quantum dot (QD) material, or other suitable materials according to requirements, but the disclosure is not limited thereto. The electronic device may have a peripheral system such as a drive system, a control system, a light source system, etc., to support a display device, an antenna device, a wearable device (for example, including an augmented reality or a virtual reality device), a vehicle-mounted device (for example, including a car windshield), or a tiling device. It should be noted that the electronic device may be any combination of the above, but the disclosure is not limited thereto. The following takes an electronic device as an example to illustrate the disclosure, but the disclosure is not limited thereto.

It should be noted that in the following embodiments, the features in several different embodiments may be replaced, recombined, and mixed to complete other embodiments without departing from the spirit of the disclosure. Features in various embodiments may all be mixed and matched as long as they do not violate the spirit of the disclosure or conflict with each other.

Hereinafter, reference will be made in detail to exemplary embodiments of the disclosure, and examples of the exemplary embodiments are illustrated in the figures. Wherever possible, the same reference numerals are used in the drawings and descriptions to refer to the same or like portions.

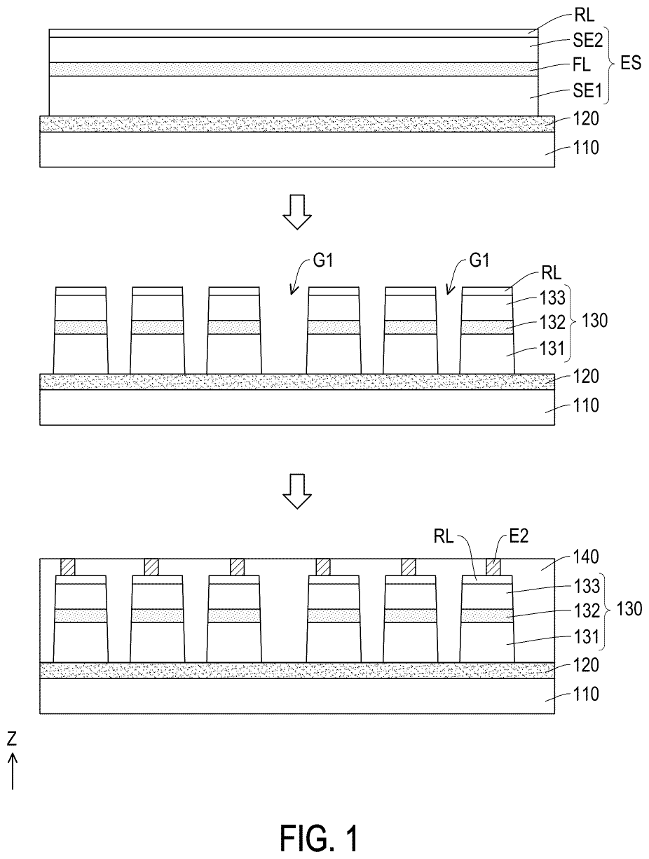

FIG. 1 to FIG. 6 are schematic cross-sectional views of the manufacturing method of the electronic device of the first embodiment of the disclosure. In particular, the manufacturing method of an electronic device 100 of the present embodiment may include the following steps:

First, referring to FIG. 1, a base layer 110 is provided, a buffer layer 120 is formed on the base layer 110, a light-emitting element layer ES is formed on the buffer layer 120, and a reflective layer RL is formed on the light-emitting element layer ES. In the present embodiment, the material of the base layer 110 may be recycled silicon wafer, but the disclosure is not limited thereto. The buffer layer 120 may be used to facilitate the light-emitting element layer ES to be formed on the base layer 110. The buffer layer 120 may have a multi-layer structure, and the material of the buffer layer 120 may include aluminum nitride (AlN), aluminum gallium nitride (AlGaN), gallium nitride (GaN), etc., but the disclosure is not limited thereto. The light-emitting element layer ES may include a first semiconductor material layer SE1, a light-emitting material layer FL, and a second semiconductor material layer SE2. The first semiconductor material layer SE1 is disposed between the light-emitting material layer FL and the buffer layer 120, the light-emitting material layer FL is disposed between the second semiconductor material layer SE2 and the first semiconductor material layer SE1, and the second semiconductor material layer SE2 is disposed between the reflective layer RL and the light-emitting material layer FL. The material of the first semiconductor material layer SE1 may be an N-type semiconductor material (such as N-type gallium nitride), and the material of the second semiconductor material layer SE2 may be a P-type semiconductor material (such as P-type gallium nitride), but the disclosure is not limited thereto. In some embodiments, the material of the first semiconductor material layer may also be a P-type semiconductor material, and the material of the second semiconductor material layer may also be an N-type semiconductor material. In the present embodiment, the material of the reflective layer RL may include aluminum or silver, but the disclosure is not limited thereto. The reflective layer RL may be used to reflect the light emitted by light-emitting elements 130 to improve luminous efficiency.

Please continue to refer to FIG. 1, the reflective layer RL and the light-emitting element layer ES are patterned to form a plurality of light-emitting elements 130. Specifically, in the present embodiment, the reflective layer RL, the first semiconductor material layer SE1, the light-emitting material layer FL, and the second semiconductor material layer SE2 may be etched using, for example, a platform process (MESA) to expose a portion of the buffer layer 120 and form the plurality of light-emitting elements 130. In particular, the plurality of light-emitting elements 130 may include a first semiconductor layer 131, a light-emitting layer 132, and a second semiconductor layer 133. The plurality of light-emitting elements 130 are separated from each other, and there is a gap G1 between two adjacent light-emitting elements 130. In the present embodiment, the plurality of light-emitting elements 130 may emit light of the same color, and the plurality of light-emitting elements 130 may be, for example, a vertical chip type, but the disclosure is not limited thereto.

Please continue to refer to FIG. 1, after the step of patterning the reflective layer RL and the light-emitting element layer ES to form the plurality of light-emitting elements 130, the second electrode E2 is formed on the patterned reflective layer RL, and the plurality of light-emitting elements 130, the reflective layer RL, and the second electrode E2 are covered using a molding compound layer 140. In the present embodiment, the second electrode E2 may be electrically connected to the second semiconductor layer 133 of the light-emitting elements 130 via the reflective layer RL. The molding compound layer 140 may be filled in the gap G1, and the molding compound layer 140 may expose the surface of the second electrode E2 facing away from the light-emitting elements 130. The material of the molding compound layer 140 may include epoxy, polydimethylsiloxane (PDMS), other suitable materials, or a combination of the above materials.

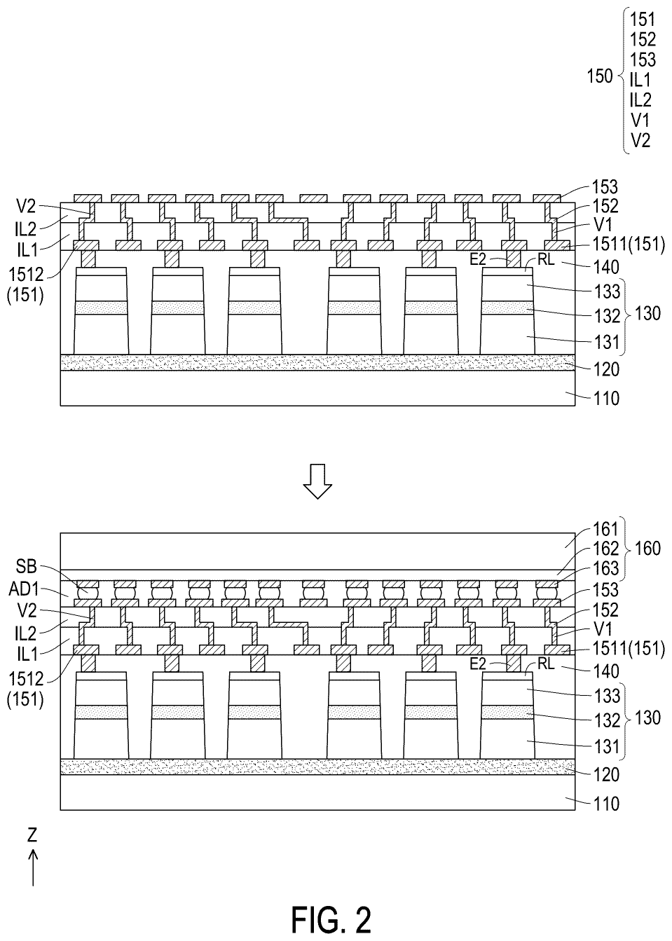

Then, referring to FIG. 2, a connection layer 150 is formed on the plurality of light-emitting elements 130 and on the molding compound layer 140. In the present embodiment, the connection layer 150 may be a redistribution layer (RDL) or a redistribution structure, but the disclosure is not limited thereto. In particular, the redistribution layer (or the redistribution structure) may include at least one insulating layer and at least one conductive layer, and the redistribution layer (or the redistribution structure) may redistribute the circuits of the electronic device 100 and/or further increase the circuit fan-out area; or, different electronic elements may be electrically connected to each other via the redistribution layer (or the redistribution structure); or, the redistribution layer (or the redistribution structure) may be used to redistribute the chip circuit fan-out or fan-in contact pad size of the chip.

Specifically, the connection layer 150 may include a plurality of conductive layers (i.e., a first conductive layer 151, a second conductive layer 152, a third conductive layer 153), a plurality of insulating layers (i.e., a first insulating layer IL1 and a second insulating layer IL2), and a plurality of vias (i.e., a first via V1 and a second via V2). The first conductive layer 151 is disposed on the molding compound layer 140. The first conductive layer 151 includes a first pad 1511 and a second pad 1512, the second pad 1512 is in contact with the second electrode E2, and the first pad 1511 is not in contact with the second electrode E2. The first insulating layer IL1 is disposed on the first conductive layer 151, and the first insulating layer IL1 may cover a portion of the molding compound layer 140. The second conductive layer 152 is disposed on the first insulating layer IL1. The second insulating layer IL2 is disposed on the second conductive layer 152, and the second insulating layer IL2 may cover a portion of the first insulating layer IL1. The third conductive layer 153 is disposed on the second insulating layer IL2. The first via V1 penetrates the first insulating layer IL1, and the first via V1 may be connected to the second conductive layer 152 and the first conductive layer 151. The second via V2 penetrates the second insulating layer IL2, and the second via V2 may be connected to the third conductive layer 153 and the second conductive layer 152. In particular, the first insulating layer IL1 and the second insulating layer IL2 may be sequentially stacked on the molding compound layer 140 along a direction Z (for example, the normal direction of the base layer 110 or the normal direction of the electronic device 100). In the present embodiment, the material of the first conductive layer 151, the second conductive layer 152, and the third conductive layer 153 may include a metal material, a transparent conductive material, other suitable conductive materials, or a combination of the above, but the disclosure is not limited thereto. The first insulating layer IL1 and the second insulating layer IL2 may have a single-layer structure or a multi-layer structure, and the material of the first insulating layer IL1 and the second insulating layer IL2 may include polyimide (PI), glass, epoxy resin, silane coupling, photosensitive material, build-up material, or a combination of the above, but the disclosure is not limited thereto.

Please continue to refer to FIG. 2, a driving substrate 160 is provided, the connection layer 150 is bonded onto the driving substrate 160, and an underfill AD1 is formed between the driving substrate 160 and the connection layer 150. In the present embodiment, the driving substrate 160 includes a base 161, a circuit layer 162, and a pad 163. The circuit layer 162 is disposed on the base 161. The circuit layer 162 may include a driving circuit such as a transistor and a metal wire not shown, and the circuit layer 162 may drive the light-emitting elements 130 to emit light. The pad 163 is disposed on the circuit layer 162, and the pad 163 may be electrically connected to the circuit layer 162. The pad 163 of the driving substrate 160 may be bonded and electrically connected to the third conductive layer 153 of the connection layer 150 via a solder ball SB, but the disclosure is not limited thereto. In some embodiments not shown, additional solder balls may not be needed. Instead, a method of metal-to-metal bonding is used so that the pad of the driving substrate may be directly bonded to the third conductive layer of the connection layer. In the present embodiment, the material of the solder ball SB may include metal, such as tin, tin silver, tin silver bismuth, tin gold, tin nickel gold, nickel gold, other suitable materials, or a combination of the above materials. The material of the underfill AD1 may include acrylic, epoxy resin, resin, photoresist material, other suitable materials, or a combination of the above materials. The material of the base 161 may be a silicon wafer, but the disclosure is not limited thereto. The driving substrate 160 may be a complementary metal-oxide-semiconductor (CMOS) substrate or a thin-film transistor substrate, but the disclosure is not limited thereto.

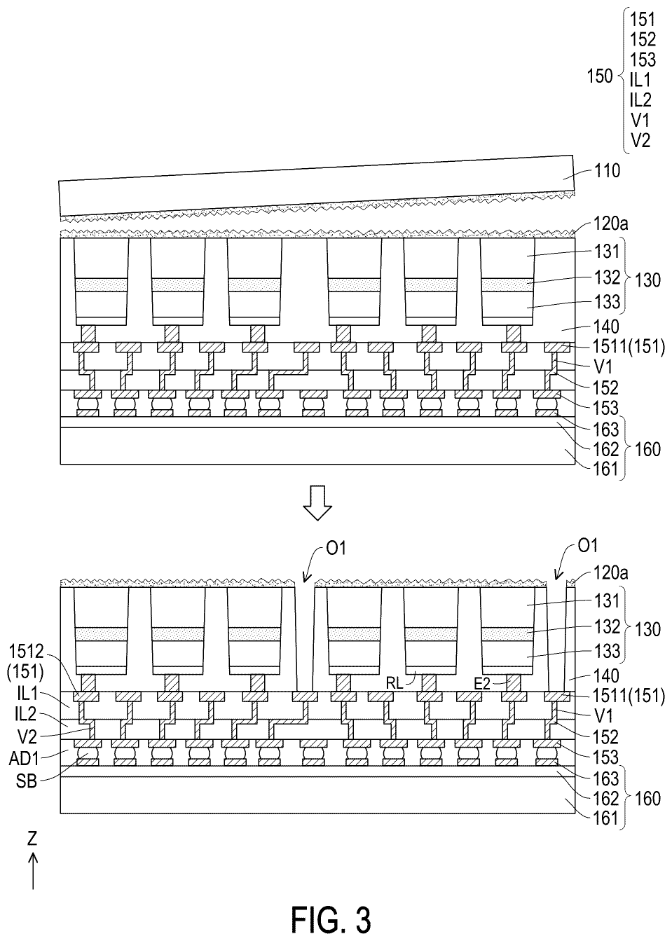

Then, please refer to FIG. 3. After flipping upside down, laser is applied to the buffer layer 120, so that the base layer 110 and the plurality of light-emitting elements 130 are separated from each other, and a buffer layer 120a having a rough surface is formed on the light-emitting elements 130. In the present embodiment, the removed base layer 110 may be recycled and reused.

Please continue to refer to FIG. 3, an opening O1 is formed in the molding compound layer 140 to expose a portion of the connection layer 150. In the present embodiment, the opening O1 penetrating the buffer layer 120a and the molding compound layer 140 is formed at a position between two adjacent light-emitting elements 130 via, for example, a method of laser drilling. In particular, the opening O1 may expose a portion of the first pad 1511 of the first conductive layer 151 of the connection layer 150.

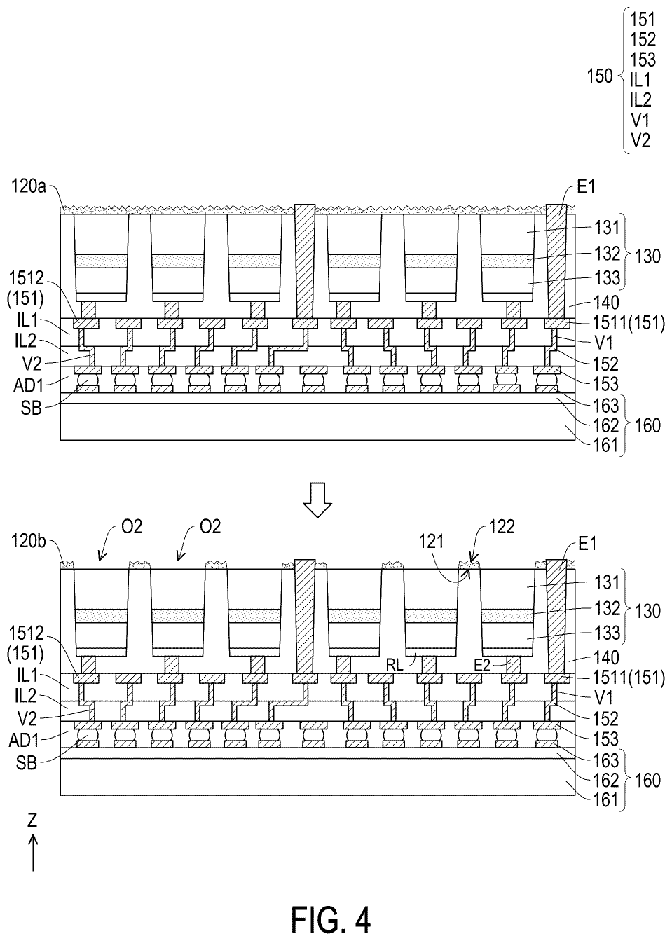

Then, referring to FIG. 4, a conductive material is filled into the opening O1 to form the first electrode E1.

Please continue to refer to FIG. 4 in which a portion of the buffer layer 120a remaining on the plurality of light-emitting elements 130 is removed to form a buffer structure 120b (i.e., another portion of the buffer layer 120a that is not removed). In the present embodiment, the buffer structure 120b includes a plurality of openings O2, and the plurality of openings O2 may expose the first semiconductor layer 131 of the plurality of light-emitting elements 130. The buffer structure 120b has a first surface 121 and a second surface 122 opposite to each other. The second surface 122 is farther away from the plurality of light-emitting elements 130 than the first surface 121, and the second surface 122 may be a rough surface.

In the present embodiment, the rough surface (i.e., the second surface 122) of the buffer structure 120b may be used to scatter the light irradiated by the light-emitting elements 130 and passing through the buffer structure 120b to reduce the impact of the light on the light emitted by other light-emitting elements adjacent to the light-emitting elements 130; this design may reduce the probability of light mixing between two adjacent light-emitting elements 130, reduce the probability of light mixing between pixels of different colors, or collect light to improve light efficiency.

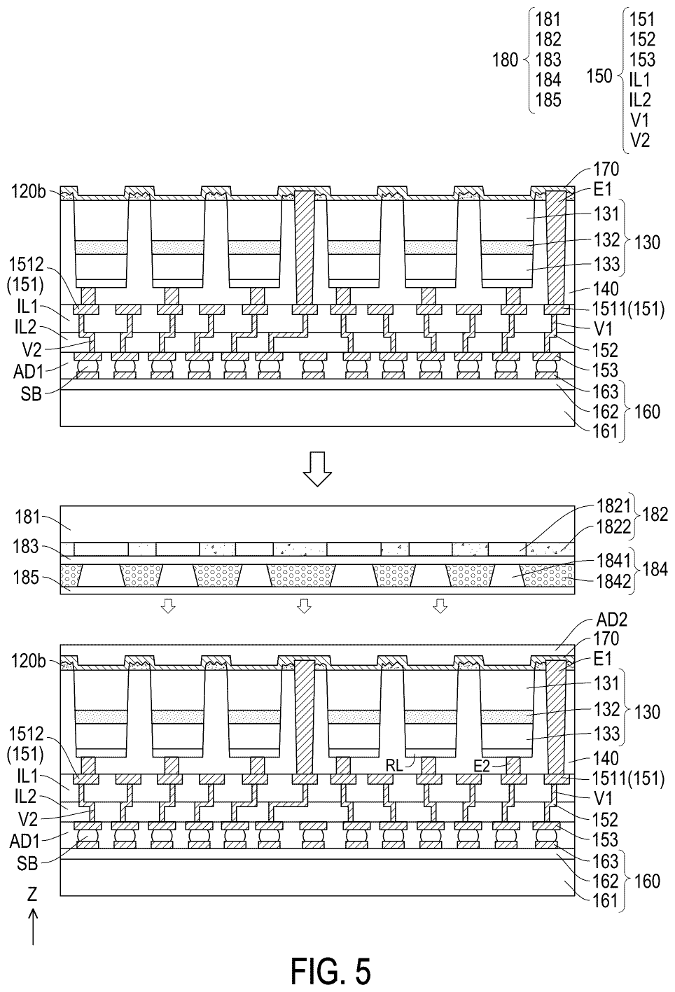

Then, please refer to FIG. 5 in which a transparent conductive layer 170 is formed on the buffer structure 120b and in the plurality of openings O2, so that the transparent conductive layer 170 may be in contact with the conductive material of the first electrode E1 and the first semiconductor layer 131 of the light-emitting elements 130. As a result, the first electrode E1 may be electrically connected to the first semiconductor layer 131 of the light-emitting elements 130 via the transparent conductive layer 170. In the present embodiment, the material of the transparent conductive layer 170 may include transparent conductive oxide (TCO) such as indium tin oxide (ITO), indium zinc oxide (IZO), or indium gallium oxide (IGO), or a combination of the above, but the disclosure is not limited thereto.

Please continue to refer to FIG. 5, in which an adhesive layer AD2 is formed on the transparent conductive layer 170, and the optical module 180 is bonded to a side of the plurality of light-emitting elements 130 away from the driving substrate 160 via the adhesive layer AD2. In the present embodiment, the material of the adhesive layer AD2 may include optical adhesive (optically clear adhesive, OCA) or transparent optical resin (optically clear resin, OCR), but the disclosure is not limited thereto. The optical module 180 may include a substrate 181, a color filter layer 182, an insulating layer 183, a light conversion layer 184, and an insulating layer 185. The color filter layer 182 is disposed under the substrate 181, and the color filter layer 182 is disposed between the substrate 181 and the light conversion layer 184. The insulating layer 183 is disposed under the color filter layer 182. The light conversion layer 184 is disposed under the insulating layer 183. The insulating layer 185 is disposed under the light conversion layer 184.

In the present embodiment, the color filter layer 182 includes a filter unit 1821 and a black matrix layer 1822. In the direction Z (for example, the normal direction of the driving substrate 160 or the normal direction of the electronic device 100), the filter unit 1821 is overlapped with and corresponds to the light-emitting elements 130, and the black matrix layer 1822 is overlapped with and corresponds to the buffer structure 120b.

In the present embodiment, the light conversion layer 184 includes a light conversion unit 1841 and a separation layer 1842. In the direction Z, the light conversion unit 1841 is overlapped with and corresponds to the light-emitting elements 130 and the filter unit 1821, and the separation layer 1842 is overlapped with and corresponds to the buffer structure 120b and the black matrix layer 1822. In the present embodiment, the separation layer 1842 may include a colored photoresist, such as a white photoresist or a black photoresist, but the disclosure is not limited thereto.

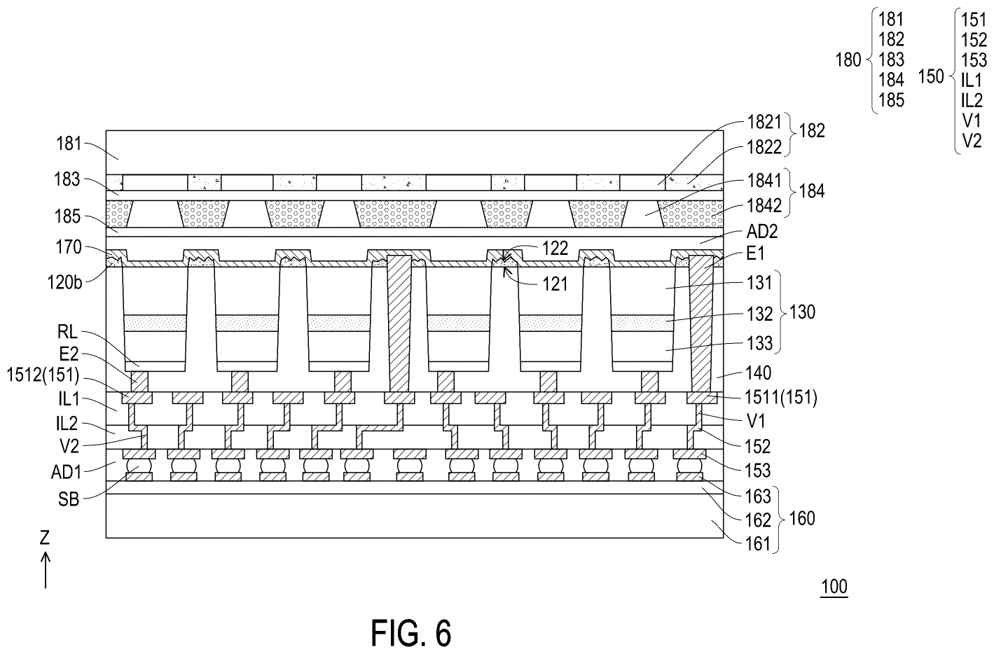

Then, please refer to FIG. 6, the electronic device 100 of the present embodiment may include the driving substrate 160, the connection layer 150, the plurality of light-emitting elements 130, the molding compound layer 140, the reflective layer RL, the buffer structure 120b, the transparent conductive layer 170, the adhesive layer AD2, and the optical module 180.

Specifically, the connection layer 150 is disposed on the driving substrate 160, and the connection layer 150 is disposed between the plurality of light-emitting elements 130 and the driving substrate 160. The connection layer 150 may be electrically connected to the driving substrate 160 via the solder ball SB. In the present embodiment, via the arrangement of the connection layer 150, the plurality of light-emitting elements 130 of the electronic device 100 may be integrated onto the driving substrate 160.

The plurality of light-emitting elements 130 are disposed on the connection layer 150, and the plurality of light-emitting elements 130 may be electrically connected to the driving substrate 160 via the connection layer 150.

The reflective layer RL is disposed between the plurality of light-emitting elements 130 and the molding compound layer 140. The reflective layer RL is disposed at a side of the plurality of light-emitting elements 130 adjacent to the connection layer 150.

The buffer structure 120b is disposed on the plurality of light-emitting elements 130, and the buffer structure 120b is disposed between the light conversion layer 184 of the optical module 180 and the plurality of light-emitting elements 130. The buffer structure 120b includes the plurality of openings O2, and the plurality of openings O2 may be overlapped in the direction Z and correspond to the plurality of light-emitting elements 130.

The buffer structure 120b has the first surface 121 adjacent to the plurality of light-emitting elements 130 and the second surface 122 away from the plurality of light-emitting elements 130. In particular, the roughness of the second surface 122 of the buffer structure 120b may be greater than the roughness of the first surface 121, so that the buffer structure 120b may be used to scatter the light irradiated by the light-emitting elements 130 and passing through the buffer structure 120b to reduce the impact of the light on the light emitted by other light-emitting elements adjacent to the light-emitting elements 130, thereby reducing the probability of light mixing between two adjacent light-emitting elements 130, reducing the probability of light mixing between pixels of different colors, or collecting light to improve light efficiency.

The transparent conductive layer 170 is disposed on the buffer structure 120b, and the transparent conductive layer 170 may be electrically connected to the plurality of light-emitting elements 130 via the plurality of openings O2.

The adhesive layer AD2 is disposed on the transparent conductive layer 170, and the adhesive layer AD2 is disposed between the optical module 180 and the buffer structure 120b.

The optical module 180 is disposed on the buffer structure 120b and the adhesive layer AD2. The optical module 180 includes the light conversion layer 184 and the color filter layer 182 disposed on the light conversion layer 184. The light conversion layer 184 is disposed between the color filter layer 182 and the buffer structure 120b.

Other examples are listed below as illustrations. It should be noted here that the following embodiments adopt the reference numerals and a portion of the content of the above embodiments, wherein the same reference numerals are used to represent the same or similar elements, and the description of the same technical content is omitted. For descriptions of omitted portions, reference may be made to the above embodiments and are not repeated in the following embodiments.

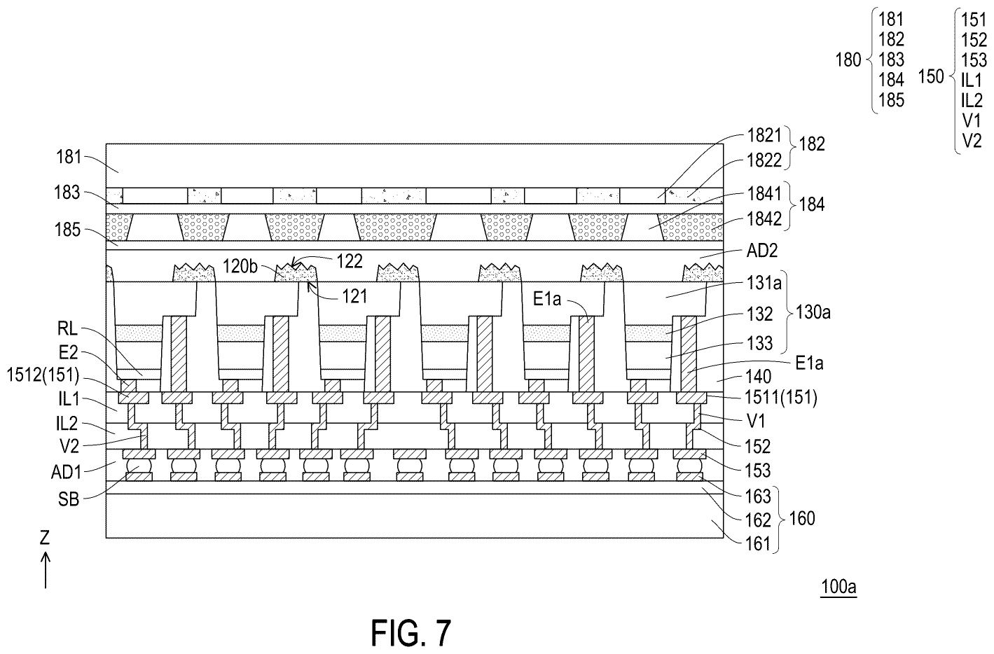

FIG. 7 is a schematic cross-sectional view of the electronic device of the second embodiment of the disclosure. Please refer to FIG. 7 and FIG. 6 at the same time. An electronic device 100a of the present embodiment is similar to the electronic device 100 of FIG. 6. The differences between the two are: in the electronic device 100a of the present embodiment, light-emitting elements 130a are flip-chip type, and the electronic device 100a of the present embodiment does not need to be provided with the transparent conductive layer 170 in the electronic device 100 shown in FIG. 6.

Specifically, please refer to FIG. 7, a first electrode Ela may penetrate the molding compound layer 140, and the first electrode Ela may be electrically connected to a first semiconductor layer 131a of the light-emitting elements 130a and the first pad 1511 of the first conductive layer 151. The first electrode Ela may be overlapped with a portion of the first semiconductor layer 131a in the direction Z.

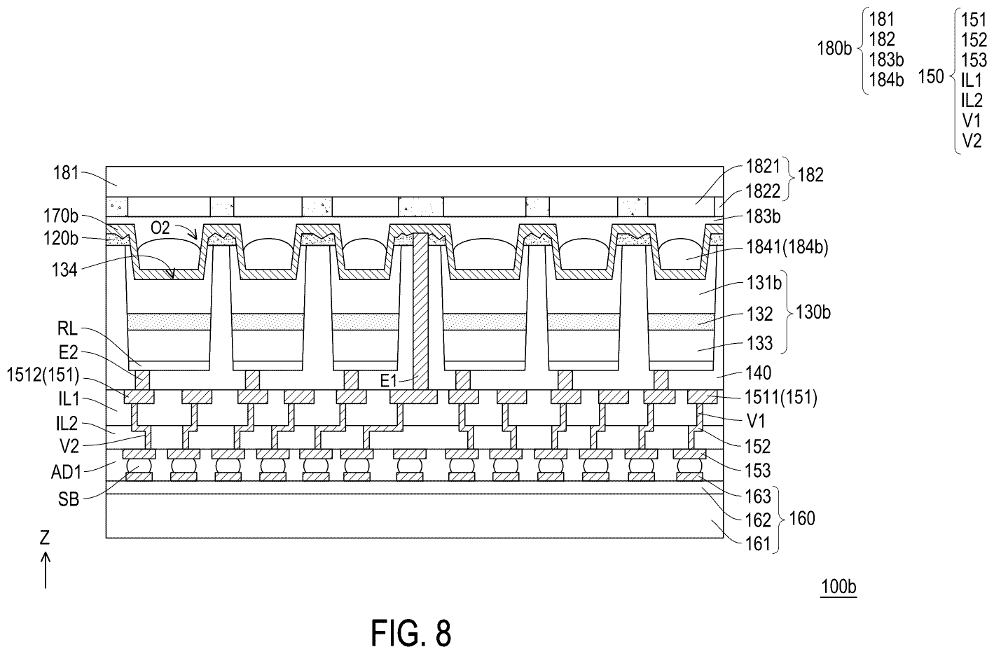

FIG. 8 is a schematic cross-sectional view of the electronic device of the third embodiment of the disclosure. Please refer to FIG. 8 and FIG. 6 at the same time. An electronic device 100b of the present embodiment is similar to the electronic device 100 of FIG. 6. The differences between the two are: in the electronic device 100b of the present embodiment, a plurality of light-emitting elements 130b further include a plurality of grooves 134, and a light conversion layer 184b of an optical module 180b is accommodated in the plurality of grooves 134.

Specifically, please refer to FIG. 8, the plurality of grooves 134 are disposed at a side of the light-emitting elements 130b away from the driving substrate 160. The grooves 134 are recessed in the first semiconductor layer 131b, and the grooves 134 may expose the first semiconductor layer 131b. In the direction Z, the grooves 134 may be overlapped with and correspond to the openings O2 of the buffer structure 120b, and the grooves 134 may be connected to the openings O2 of the buffer structure 120b.

In the present embodiment, a transparent conductive layer 170b is disposed on the buffer structure 120b, in the plurality of openings O2, and in the plurality of grooves 134. Therefore, the transparent conductive layer 170b may be electrically connected to the plurality of light-emitting elements 130b via the plurality of openings O2 and the plurality of grooves 134. In addition, the transparent conductive layer 170b may be in contact with the conductive material of the first electrode E1 and the first semiconductor layer 131b of the light-emitting elements 130b.

In the present embodiment, the optical module 180b may include the substrate 181, the color filter layer 182, the insulating layer 183b, and the light conversion layer 184b. The color filter layer 182 is disposed under the substrate 181, and the color filter layer 182 is disposed between the substrate 181 and the light conversion layer 184b. The insulating layer 183b is disposed under the color filter layer 182 and in the plurality of openings O2. The light conversion layer 184b is disposed under the insulating layer 183b and in the plurality of grooves 134. In the direction Z, the light conversion unit 1841 may be overlapped with and correspond to the light-emitting elements 130b and the filter unit 1821 of the color filter layer 182.

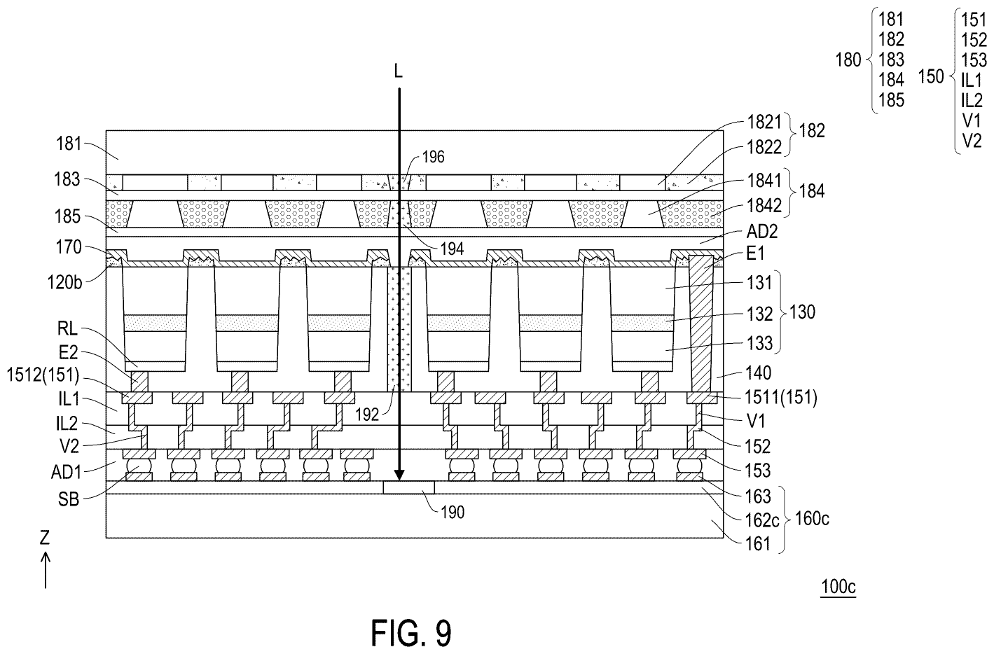

FIG. 9 is a schematic cross-sectional view of the electronic device of the fourth embodiment of the disclosure. Please refer to FIG. 9 and FIG. 6 at the same time. An electronic device 100c of the present embodiment is similar to the electronic device 100 of FIG. 6. The differences between the two are: the electronic device 100c of the present embodiment further includes a light-sensing element 190, a first transparent material layer 192, a second transparent material layer 194, and a third transparent material layer 196.

Specifically, please refer to FIG. 9, the first transparent material layer 192 is disposed between the buffer structure 120b and the connection layer 150, and the first transparent material layer 192 may penetrate the molding compound layer 140. The second transparent material layer 194 is disposed between the insulating layer 183 and the insulating layer 185 of the optical module 180, and the second transparent material layer 194 may penetrate the separation layer 1842 of the light conversion layer 184. The third transparent material layer 196 is disposed between the substrate 181 and the insulating layer 183 of the optical module 180, and the second transparent material layer 194 may penetrate the black matrix layer 1822 of the color filter layer 182. In the present embodiment, the material of the first transparent material layer 192, the second transparent material layer 194, and the third transparent material layer 196 may include optical adhesive (OCA) or transparent optical adhesive (OCR), but the disclosure is not limited thereto.

The light-sensing element 190 is disposed in a circuit layer 162c of the driving substrate 160c. In the direction Z, the light-sensing element 190, the first transparent material layer 192, the second transparent material layer 194, and the third transparent material layer 196 are overlapped with and correspond to each other, and the light-sensing element 190 is not overlapped with the light-emitting elements 130. As a result, an external optical signal L may enter the electronic device 100c substantially along the path of the first transparent material layer 192, the second transparent material layer 194, and the third transparent material layer 196 in the connection direction to be detected by the light-sensing element 190.

In the present embodiment, the light-sensing element 190 may be used, for example, for human eye recognition and tracking; or for measuring ambient light intensity to adjust the display brightness of the electronic device 100c.

In some embodiments not shown, the first transparent material layer may also penetrate downward through the connection layer and the underfill to be extended to the light-sensing element.

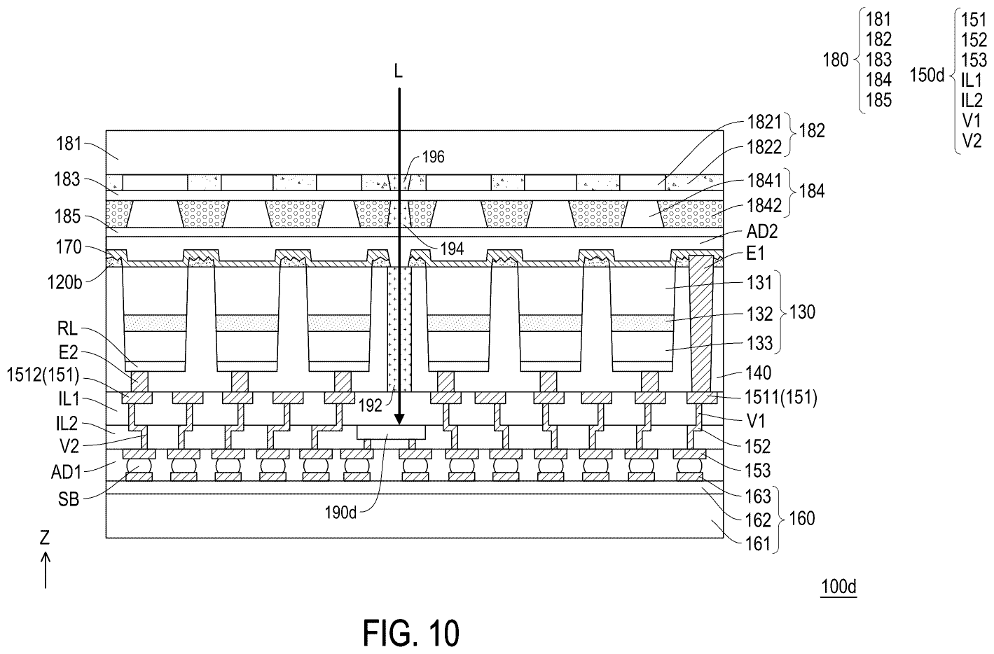

FIG. 10 is a schematic cross-sectional view of the electronic device of the fifth embodiment of the disclosure. Please refer to FIG. 10 and FIG. 9 at the same time. An electronic device 100d of the present embodiment is similar to the electronic device 100c of FIG. 9. The differences between the two are: in the electronic device 100d of the present embodiment, a light-sensing element 190d is disposed in the second insulating layer IL2 of the connection layer 150d. The light-sensing element 190d may be electrically connected to the driving substrate 160 via the connection layer 150d.

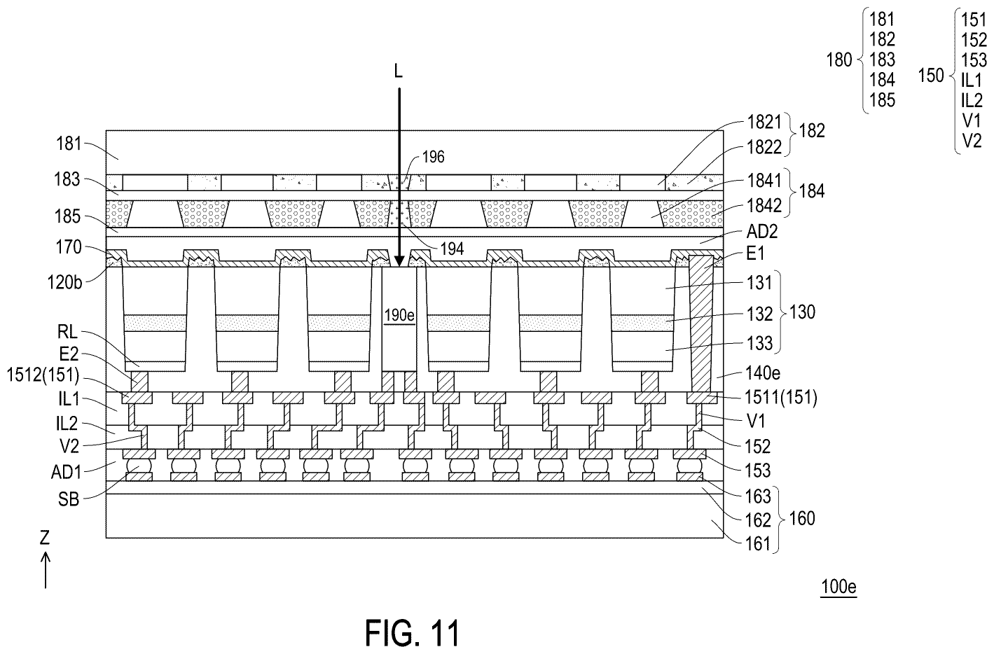

FIG. 11 is a schematic cross-sectional view of the electronic device of the sixth embodiment of the disclosure. Please refer to FIG. 11 and FIG. 9 at the same time. An electronic device 100e of the present embodiment is similar to the electronic device 100c of FIG. 9. The differences between the two are: in the electronic device 100e of the present embodiment, a light-sensing element 190e is disposed in a molding compound layer 140e.

Specifically, please refer to FIG. 11, the light-sensing element 190e is disposed between the buffer structure 120b and the connection layer 150, and the light-sensing element 190e may be electrically connected to the driving substrate 160 via the connection layer 150. In addition, the external optical signal L may enter the electronic device 100e substantially along the path of the second transparent material layer 194 and the third transparent material layer 196 in the connection direction to be detected by the light-sensing element 190e.

Based on the above, in the electronic device and the manufacturing method thereof of an embodiment of the disclosure, since the second surface of the buffer structure is a rough surface, and the roughness of the second surface of the buffer structure is greater than the roughness of the first surface, the light irradiated by the light-emitting elements and passing through the buffer structure may be scattered. Therefore, the impact of the light on the light emitted by other light-emitting elements adjacent to the light-emitting elements may be reduced, the probability of light mixing between two adjacent light-emitting elements may be reduced, the probability of light mixing between pixels of different colors may be reduced, or light may be collected to improve light efficiency.

Lastly, it should be noted that the above embodiments are used to describe the technical solution of the disclosure instead of limiting it. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

What is claimed is:

1. An electronic device, comprising:
a driving substrate;
a connection layer disposed on the driving substrate;
a plurality of light-emitting elements electrically connected to the driving substrate via the connection layer; and
a buffer structure disposed on the plurality of light-emitting elements and comprising a plurality of openings, wherein the plurality of openings are overlapped with the plurality of light-emitting elements;
wherein the buffer structure has a first surface adjacent to the plurality of light-emitting elements and a second surface away from the plurality of light-emitting elements, and a roughness of the second surface is greater than a roughness of the first surface.

2. The electronic device of claim 1, further comprising:
an optical module disposed on the buffer structure and comprising a light conversion layer and a color filter layer disposed on the light conversion layer.

3. The electronic device of claim 2, further comprising:
an adhesive layer disposed between the optical module and the buffer structure.

4. The electronic device of claim 2, wherein the light conversion layer comprises a light conversion unit and a separation layer, the light conversion unit is overlapped with the plurality of light-emitting elements, and the separation layer is overlapped with the buffer structure.

5. The electronic device of claim 2, wherein the color filter layer comprises a filter unit and a black matrix layer, the filter unit is overlapped with the plurality of light-emitting elements, and the black matrix layer is overlapped with the buffer structure.

6. The electronic device of claim 1, further comprising:
a transparent conductive layer disposed on the buffer structure and electrically connected to the plurality of light-emitting elements via the plurality of openings.

7. The electronic device of claim 1, wherein the plurality of light-emitting elements comprise a plurality of grooves, and the electronic device further comprises:
a light conversion layer accommodated in the plurality of grooves.

8. The electronic device of claim 7, wherein the plurality of grooves are disposed at a side of the plurality of light-emitting elements away from the driving substrate.

9. The electronic device of claim 7, wherein the plurality of grooves are overlapped with the plurality of openings.

10. The electronic device of claim 1, further comprising:
a molding compound layer covering the plurality of light-emitting elements.

11. The electronic device of claim 10, further comprising:
a reflective layer disposed between the plurality of light-emitting elements and the molding compound layer.

12. The electronic device of claim 1, wherein the connection layer comprises a plurality of conductive layers, a plurality of insulating layers, and a plurality of vias.

13. The electronic device of claim 1, further comprising:
a light-sensing element disposed in the driving substrate or in the connection layer.

14. The electronic device of claim 1, wherein the light-sensing element is not overlapped with the plurality of light-emitting elements.

15. The electronic device of claim 1, further comprising:
a molding compound layer covering the plurality of light-emitting elements; and
a light-sensing element disposed in the molding compound layer.

16. A manufacturing method of an electronic device, comprising:
providing a base layer;
forming a buffer layer on the base layer;
forming a light-emitting element layer on the buffer layer;
patterning the light-emitting element layer to form a plurality of light-emitting elements;
forming a connection layer on the plurality of light-emitting elements;
bonding the connection layer onto the driving substrate;
applying a laser onto the buffer layer to separate the base layer and the plurality of light-emitting elements from each other; and
removing a portion of the buffer layer remaining on the plurality of light-emitting elements to form a buffer structure, wherein the buffer structure comprises a plurality of openings, and the plurality of openings expose the plurality of light-emitting elements.

17. The manufacturing method of claim 16, further comprising:
attaching an optical module to a side of the plurality of light-emitting elements away from the driving substrate.

18. The manufacturing method of claim 17, wherein the optical module comprises a substrate, a light conversion layer, and a color filter layer, and the color filter layer is disposed between the substrate and the light conversion layer.

19. The manufacturing method of claim 16, further comprising, after the step of patterning the light-emitting element layer to form the plurality of light-emitting elements:
covering the plurality of light-emitting elements using a molding compound layer.

20. The manufacturing method of claim 19, further comprising:
forming an opening in the molding compound layer to expose a portion of the connection layer;
filling a conductive material into the opening; and
forming a transparent conductive layer on the buffer structure so that the transparent conductive layer is in contact with the conductive material.
